(19) United States
(12) Patent Application Publication
(10) Pub. No.: US 2008/0264486 A1
(43) Pub. Date: Oct. 30, 2008

(54) Guided-wave photovoltaic devices

(76) Inventors: Xiaoyuan Chen, Acton, MA (US); Gang Chen, Carlisle, MA (US)

Correspondence Address: JOSEPH STECEWYCZ, P.O. BOX 1309, GROTON, MA, 01450, US

(21) Appl. No.: 12/150,774

(22) Filed: Apr. 30, 2008

Related U.S. Application Data
(60) Provisional application No. 60/927,022, filed on Apr. 30, 2007.

(51) Int. Cl. H01L 31/04; B05D 5/12

(52) U.S. Cl. 136/259; 427/74; 136/252

(57) ABSTRACT

A photovoltaic device comprises: a first cladding material; a photosensitive material having an index of refraction larger than the first cladding material index of refraction, the photosensitive material disposed adjacent the first cladding material; and a second cladding material having an index of refraction smaller than the photosensitive material index of refraction, the photosensitive material disposed between the first cladding material and the second cladding material so as to form a waveguide for confining propagating photons; and first and second electrodes in electrical contact with the photosensitive material.

### CROSS-REFERENCE TO RELATED APPLICATION

The present Application claims the benefit of Provisional Patent Application No. 60/927,022 entitled “Guided-wave photovoltaic devices,” filed 30 Apr. 2007 and incorporated by reference herein in its entirety.

### FIELD OF THE INVENTION

The present invention relates to photovoltaic devices and, more particularly, to waveguide-based photovoltaic cells.

### BACKGROUND OF THE INVENTION

Current thin-film based photovoltaic cells such as semiconductor silicon (Si), dye sensitized, and organic solar cells, have limited light absorption or interaction lengths resulting in lower photon-to-electricity conversion efficiency, since a large fraction of incident solar radiation cannot be absorbed in the device over such limited interaction lengths. For silicon thin-film cells in particular, a method of enhancing the light absorption is desirable because of the weaker light absorption ability of silicon as a consequence of its indirect bandgap.

A variety of light trapping mechanisms have been explored for thin-film photovoltaic cells. However, the light trapping efficiency of conventional cell configurations has practical limitations. In organic cells, for example, the strong exciton bonding energy and fast recombination of the photon-generated electrons and holes, and the slow diffusion of carriers, require photosensitive region thin enough so that charges can be separated before recombination. In a typical configuration, the thickness of a photosensitive region in an organic cell may be on the order of several tens of nanometers. Such dimensions result in a low absorption rate of incident solar radiation.

Similarly, in dye-sensitized cells photosensitive dyes are used in the monolayer form to promote exciton separation. Total thickness of the photosensitive region is consequently limited by charge transport through porous materials that support the dye. It can be appreciated that increasing light interaction length in both organic and dye sensitized cells could be more beneficial to the conversion efficiency.

Thin-film photovoltaic cells may typically comprise several thin layers including: a transparent substrate (or superstrate), an anti-reflection coating, p-doped and n-doped regions, a photosensitive region, and electrodes. In the case of dye-sensitized solar cells, the p-doped and n-doped regions may not be thin films, but the general discussions below are still applicable. In addition to incomplete photon absorption, other loss mechanisms may be present in the conversion process. For example, absorption in the electrodes and free carrier absorptions in p-dope and n-doped regions may lower device efficiency.

Furthermore, it is known in the art that the optical mode profile along light incidental direction may be a concern for photovoltaic devices. Ideally, the optical mode profile should exhibit a peak at the active region where electron-hole pairs generation occurs, especially in very thin active region of organic cells. As the mode profile is a function of the layer thickness and material optical index, uniformity of thickness is necessary to achieve overall cell efficiency and an acceptable manufacturing yield. In a cell with a reflection type of light trapping, such as corrugated structures, partially collected photons undergo multiple scatterings and reflections inside the thin film. Such multiple scattering also increases absorption loss in the electrodes, and free carrier absorptions in p-type and n-type regions.

The emission of the sun has a broad energy spectrum. Incident photons having energies below the bandgap levels of semiconductors (or the HOMO and LUMO separations of dyes and polymers) cannot generate electron-hole pairs in the photovoltaic device and are effectively wasted. On the other hand, the electrons generated by photons having energies greater than the semiconductor bandgap may lose their excess energy as heat to a material lattice before reaching the device electrodes. To recover some of the lost energies, technologies have been developed to capture photons of different energies or wavelengths by using films with different bandgaps, for example, based on stacking different group III-V materials to form so-called multi-junction cells.

Many thin-film deposition techniques have been developed to fabricate such multi-junction cells. However, manufacturing challenges still remain to fabricate stacked multiplayer thin films with high qualities, both electronic and optical. Growth temperature, dopants, lattice mismatching between materials, layer interface qualities, and transparent electrodes, to name a few, are all potential factors that limit the capability and freedom to select highly absorptive materials, substrates, and electrode materials. These complexities, which affect film growth, need to be addressed before massive industrial production of low cost solar cells can occur. In addition, current matching is important in such vertically stacked layers because of the mechanism by which electrons and holes transverse all layers sequentially before being extracted out.

In the present state of the art, semiconductor silicon remains a primary candidate for the solar photovoltaics industry because of its availability and reliability, despite its low light-absorption coefficient due to its intrinsic indirect band-gap. It can be appreciated that, to match growing needs for future clean energy needs, high efficiency photovoltaic devices with cost and material saving productions are ultimately required.

Concentrating solar radiation on a photovoltaic cell is a technique known in the art to reduce the required area of photovoltaic cells for cost reduction. Accordingly, a variety of solar concentrators have been developed, such as refractive, diffraction (Fresnel lens), and reflective. Both focusing and non-focusing optics have been used. In the technique of diverting and concentrating solar radiation onto photovoltaics, high cell efficiency becomes critical because of tracking requirements and extra cost in maintaining tracking mechanisms. Multi-junction cells based on group III-V semiconductors are available for those applications where the efficiency consideration of the cells is greater than the cost consideration.

Many concentrated photovoltaic systems rely on large concentrators with high concentration ratios. One such technique uses micron-sized concentrators in combination with a reflective-type of photon trapping structures for thin-film photovoltaic cells, especially polymer-cells. In addition to using smaller photovoltaic devices, the technique of concentrating solar radiation can also lead to higher cell efficiency.

In both thin-film based photovoltaic cells and bulk photovoltaic cells, photons may enter at one surface of the photovoltaic cell and propagate across the cell thickness. The weak absorption of the photosensitive materials, described above, leads to low efficiency of the thin-film based photovoltaic cells. Although light trapping techniques known in the present state of the art may increase the absorption, these techniques tend to be limited as refraction and diffraction through the light trapping structures inevitably scatter photons out of the carrier generation region.

Other techniques known in the art include usage of multiple reflections to increase the distance that light travels inside the carrier generation region. U.S. Pat. No. 6,333,458 issued to Forrest et al., for example, discloses a photon recycling photosensitive optoelectronic device utilizing a metallic film, such as silver or aluminum, to provide a reflective layer to confine light to the carrier generation region. However, the use of metallic film limits the amount of ambient diffused optical radiation that can be utilized in the carrier generation region, and the optoelectronic device requires transparent electrodes for operation. Accordingly, as the present state of the art discloses a number of different approaches to addressing the problem of increasing efficiency and production yield in photovoltaic devices, most of these solutions are configured to allow photons to enter the carrier generation region through planar interfaces at the photosensitive region and the surrounding materials, as in conventional solar cells. What is needed is a photovoltaic device having efficient light absorption in thin photosensitive layers, resulting in high energy-conversion efficiency, with attendant materials and cost saving merits.

### BRIEF SUMMARY OF THE INVENTION

In one aspect of the present invention, a photovoltaic device comprises: a first cladding material; a photosensitive material having an index of refraction larger than the first cladding material index of refraction, the photosensitive material disposed adjacent the first cladding material; and a second cladding material having an index of refraction smaller than the photosensitive material index of refraction, the photosensitive material disposed between the first cladding material and the second cladding material so as to form a waveguide for confining propagating photons; and first and second electrodes in electrical contact with the photosensitive material.

In another aspect of the present invention, a photovoltaic device comprises: a first photosensitive material disposed to receive a photon beam; a second photosensitive material having a bandgap smaller than the first photosensitive material bandgap, the second photosensitive material disposed to receive a first portion of the photon beam from the first photosensitive material; and a third photosensitive material having a bandgap smaller than the second photosensitive material bandgap, the third photosensitive material disposed to receive a second portion of the photon beam from the second photosensitive material.

In yet another aspect of the present invention, a method for fabricating a photovoltaic device for conversion of a photon beam into electrical energy comprises: depositing a layer of a first cladding material onto a substrate; depositing a layer of photosensitive material onto the first cladding material, the photosensitive material having an index of refraction larger than the first cladding material index of refraction; and depositing a layer of a second cladding material onto the photosensitive material, the second cladding material having an index of refraction smaller than the photosensitive material index of refraction.

The additional features and advantage of the disclosed invention is set forth in the detailed description which follows, and will be apparent to those skilled in the art from the description or recognized by practicing the invention as described, together with the claims and appended drawings.

Disclosed herein are various embodiments of guided-wave photovoltaic devices, the embodiments functioning to concentrate an incident photon beam into a predefined optical path. The optical path lies within a photosensitive material that forms an interface with a surrounding waveguide material. Photon-generated charge carriers are extracted from the photosensitive material in directions generally orthogonal to the photon optical path. The present invention generally provides for photovoltaic devices, such as solar photovoltaic devices, having efficient light absorption in thin photosensitive layers, resulting in high energy-conversion efficiency, with attendant materials and cost saving merits.

### BRIEF DESCRIPTIONS OF THE DRAWINGS

FIG. 1 is a diagrammatical cross-sectional view of a guided-wave photovoltaic device a photon beam concentrator, in accordance with the present invention;

FIG. 2 is a detail diagrammatical view of an end of the guided-wave photovoltaic device of FIG. 1;

FIG. 3 is a diagrammatical cross-section view of an alternative embodiment of the guided-wave photovoltaic device of FIG. 1 in which an incident photon beam is directed into the guided-wave photovoltaic device by total internal reflection;

FIG. 4 is a diagrammatical view of an optical component used to divert the incident photon beam into two guided-wave photovoltaic devices;

FIG. 5 is a diagrammatical isometric view of an exemplary embodiment of a guided-wave photovoltaic array including spherical type photon beam concentrators, in accordance with the present invention;

FIG. 6 is a diagrammatical isometric view of a channel-type guided-wave photovoltaic unit, as can be used in the guided-wave photovoltaic array of FIG. 5;

FIG. 7 is a diagrammatical isometric view of a pair of channel-type GWPV devices with a common electrode, as can be used in the guided-wave photovoltaic array of FIG. 5;

FIG. 8 is a diagrammatical isometric view of an exemplary embodiment of a guided-wave photovoltaic array including cylindrical type photon beam concentrators, in accordance with the present invention;

FIG. 9 is diagrammatical isometric view of a planar-type guided-wave photovoltaic unit, as can be used in the guided-wave photovoltaic array of FIG. 8;

FIG. 10 is a diagrammatical isometric view of a pair of planar-type GWPV devices with a common electrode, as can be used in the guided-wave photovoltaic array of FIG. 8;

FIG. 11 is a schematic side view of another exemplary embodiment of a guided-wave photovoltaic device, in accordance with the present invention, having a lambda-shaped waveguide;

FIG. 12 is a schematic side view of another exemplary embodiment of a guided-wave photovoltaic device with a waveguide core comprising material core components with different absorption band edges, the components aligned along a photon beam propagating direction, in accordance with the present invention;

FIG. 13 is a schematic side view of another exemplary embodiment of a guided-wave photovoltaic device comprising material core components with different absorption band edges, the components aligned to form a cavity such that a propagating photon beam photon beam remains substantially confined for maximum photon capture, in accordance with the present invention;

FIG. 14 is a schematic side view of an exemplary embodiment of a staking cell waveguide having a plurality of material components cells in parallel, where an incident photon beam is spectrally dispersed by an optical component;

FIG. 15 is a diagrammatical illustration of a transmissive optical concentrator used to direct an incident photon beam onto a guided-wave photovoltaic device;

FIG. 16 is a diagrammatical illustration of a reflective optical concentrator used to direct an incident photon beam onto a guided-wave photovoltaic device;

FIG. 17 shows a second photon beam concentrator disposed at a periphery of a guided wave photovoltaic device, in accordance with the present invention;

FIG. 18 shows a second photon beam concentrator disposed proximate a pair of guided wave photovoltaic devices, in accordance with the present invention;

FIG. 19 is a diagrammatical illustration of a guided-wave photovoltaic device comprising a lambda-shaped waveguide core of organic or dye-sensitized materials and a lens type photon beam imaging concentrator;

FIG. 20 is a diagrammatical illustration of a guided-wave photovoltaic device comprising a lambda-shaped waveguide core of organic or dye-sensitized materials and a lens type photon beam non-imaging concentrator;

FIG. 21 is a diagrammatical illustration of a guided-wave photovoltaic device comprising a lambda-shaped waveguide core of organic or dye-sensitized materials having a collector as a substrate;

FIG. 22 schematically depicts a cross sectional view of a reflective type Winston type photon collector on a lambda-shaped waveguide guided-wave photovoltaic device;

FIG. 23 schematically depicts a cross sectional view of a refractive type Winston type photon collector on a lambda-shaped waveguide guided-wave photovoltaic device; and

FIG. 24 is a diagrammatical illustration of a hybrid photovoltaic structure comprising a guided-wave photovoltaic organic device and a guided-wave photovoltaic inorganic cell, in accordance with the present invention.

### DETAILED DESCRIPTION OF THE INVENTION

The following detailed description is of the best currently contemplated modes of carrying out the invention. The description is not to be taken in a limiting sense, but is made merely for the purpose of illustrating the general principles of the invention, since the scope of the invention is best defined by the appended claims.

The disclosed photovoltaic devices and methods of fabrication are applicable to many different types of optical radiation conversion devices. Accordingly, although the present disclosure illustrates the innovative device and method with particular application to solar cells, those skilled in the relevant art will appreciate that the innovative device and method will find application in other photovoltaic devices. The photovoltaic devices, in accordance with the present invention, provide for an improved efficiency and economy of operation in comparison to conventional thin-film based solar cell by concentrating an incident photon beam to a predetermined size and directing the beam into a predefined optical path, such as a channel or a planar thin waveguide containing one or more photosensitive materials in the core or in the cladding. Photo-generated electrons and holes are extracted from the locations where they are generated, and guided in a generally orthogonal direction to the photon waveguide propagating direction. The disclosed photovoltaic devices combine advantages of light concentrators and wave-guides to enhance overall conversion efficiency.

Since a large amount of quality photo-voltaic materials are required in solar energy industry, material resources and cost are becoming ever growing concerns. One of the advantages of the disclosed photovoltaic devices—fabrication with relatively lesser amounts of expensive photovoltaic materials—may be achieved by the techniques of concentrating incident optical radiation and wave-guiding the concentrated optical radiation through a photosensitive material, described below. The required thickness of a photosensitive waveguide core can be specified in microns, or in tens of nanometers if used as cladding, and photons can be concentrated by inexpensive polymer, glass, and metallic concentrators. These configurations help to drastically reduce the material costs while providing for flexibility in the design of devices. Furthermore, the photon concentration ration may be readily designed such that a resulting photovoltaic module be light in weight and have thin-film type of features. Such flexible device configuration is one of many advantages of the disclosed photovoltaic devices.

In the present state of the art, a typical thin-film solar cell may have a conversion efficiency of about half of that of a bulk silicon cell, primarily because of thickness-limited light absorption of the indirect bandgap of silicon. Many light trapping methods have been developed to enhance photon interaction length in spite of having the thickness limitation. However, such light-trapping methods have not been shown to provide sufficient collection of the photons to overcome the thickness limitation. In a typical light-trapping method, light may enter into the photosensitive region from lateral surfaces, allowing scattering and absorption losses in the electrodes, which serves to degrade the efficiency of the solar cell device. In comparison, the disclosed GWPV device may be particularly useful to overcome these light-trapping deficiencies.

In general, the disclosed photovoltaic device configurations provide a number of advantages over the prior art. For example, as photons propagate generally parallel to the waveguides, the photon absorption length is not determined by film thickness but by the waveguide length. Virtually all useful photons can be absorbed using the waveguide configuration. Because the photons propagate parallel to the waveguide, device electrodes do not block incident photons, and transparent electrodes are not necessary. The component designer has greater latitude to emplace electrodes, such as placing an electrode near an electron-hole generation region, or making large electrodes to reduce series resistance.

Metallic electrode layers can be used directly as a cavity for photon recycling (i.e., for reduction of emission losses). Moreover, the waveguide can be integrated with a low-loss optical cavity, such as Bragg reflectors or photonic structures, to suppress spontaneous emission for high conversion efficiency, typically exceeding normal bulk silicon cell efficiency for silicon-based photosensitive regions.

In the waveguides disclosed herein, the light wave spatial profile can be controlled to increase the optical absorption in photosensitive region. This feature can reduce optical losses in highly doped regions, and may reduce potential electrode absorption losses. The controlled light wave spatial profile additionally provides for a photovoltaic cell design with largely reduced internal electrical resistance. The configuration of a photovoltaic device in accordance with the present invention also provides for a thin p-i-n junction that can be designed with steeper internal electric field for carrier extraction. The guide modes mean that there exist stronger electromagnetic fields in the p-i-n region. Such structures can lead to reduced scattering loss by impurities and defects. These advantages, plus shorter distances, from electron-hole generation region to electrodes, mean that photosensitive materials with lower grade crystal quality can be used without compromising conversion efficiency, leading to both manufacturing and cost-per-watt advantages.

The disclosed photovoltaic device may comprise: (i) a single or a multiple core waveguide having a single photosensitive material component, (ii) a single core waveguide with more than one photosensitive material component in a series configuration, or (iii) a waveguide comprising core cells of different photosensitive materials, each material component having a different energy absorption band or bandgap. Photosensitive materials may be included in the waveguide core and in the cladding. Photosensitive materials having optical indices comparable to the surrounding media may be used as part of the waveguide cladding while the waveguide core comprises a non-absorbing material. Interface waves can also be used between a metallic surface and the photosensitive material to increase the photon absorption. This type of waveguide configuration may be useful for a low optical index photosensitive material, such as polymer, and for a hybrid waveguide, such as a polymer on a semiconductor substrate. The photosensitive materials can also be specified such that optical radiation from the waveguide core is coupled into the photosensitive region via a tunneling mechanism.

The disclosed photovoltaic device has many other advantages in optical loss reduction, material cost, material growth, device configurations and application flexibilities. The disclosed configurations are particularly useful for the thin-film type of photovoltaic materials with low photo-absorption coefficient near the bandgap, such as silicon, because of unlimited absorption length of the relatively “long” waveguide. The disclosed configurations are also applicable to organic/Gratzel cells.

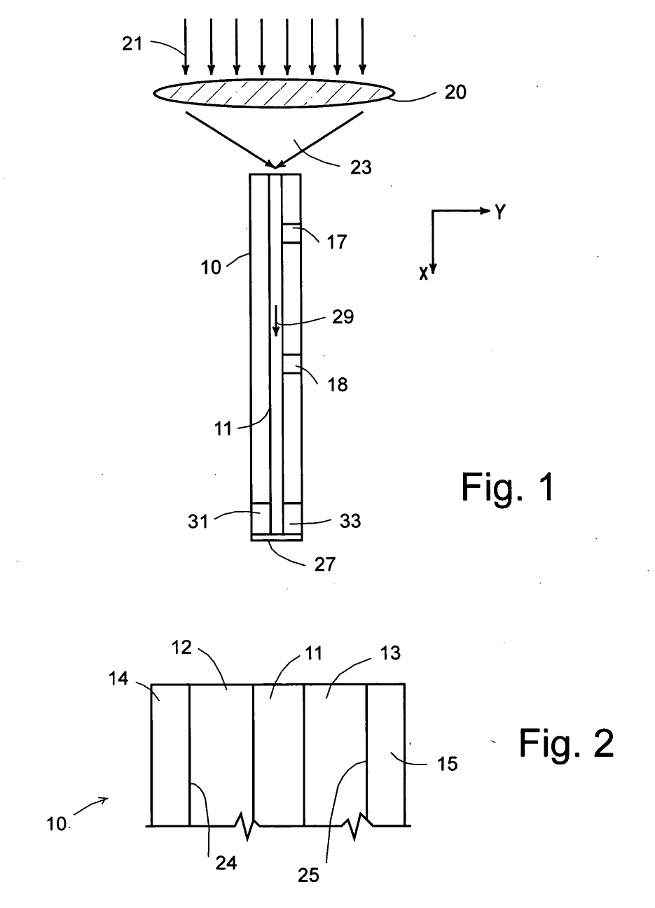

There is shown in FIGS. 1 and 2 an exemplary embodiment of a guided wave photovoltaic (hereinafter GWPV) device 10. The GWPV device 10 comprises a waveguide-type photovoltaic structure which confines and maintains an incident photon beam 21 along a preferred photon propagating direction in the GWPV device 10, generally in the x-direction of a Cartesian coordinate system as indicated by arrow 29. The GWPV device 10 comprises a waveguide core 11 that includes photosensitive material, as described in greater detail below. The waveguide core 11 may be disposed between a first inner cladding layer 12 and a second inner cladding layer 13, shown in FIG. 2. The first inner cladding layer 12 may be disposed between the waveguide core 11 and a first outer cladding layer 14, and the second inner cladding 13 may be disposed between the waveguide core 11 and a second outer cladding layer 15. In an alternative exemplary embodiment, either or both of the first outer cladding layer 14 and the second outer cladding layer 15 may comprise air.

The incident photon beam 21 may be modified into a concentrated photon beam 23 by an optical concentrator 20 disposed proximate the waveguide core 11, shown in FIG. 1. The optical concentrator 20 may comprise a focusing or non-focusing lens, such as a refractive lens or a diffractive (e.g., Fresnel) lens, or may comprise a non-imaging collector based on a total internal reflection, such as a reflective surface. Electrical charges are generated by the interaction of the concentrated photon beam 23 with the photosensitive material in the waveguide core 11. The electrical charges may be conducted out of the GWPV device 10 via a first electrode 31 and a second electrode 33, where both electrodes 31 and 33 are in electrical contact with the waveguide core 11. One or more additional electrodes 35 may be disposed in contact with the waveguide core 11, as explained in greater detail below. Alternatively, the optical concentrator 20 may comprise a combination of transmissive and reflective components, as described in greater detail below.

The beam photon refractive index of the material forming the waveguide core 11 is preferably higher than the beam photon refractive index of the material forming the inner cladding layers 12 and 13. The refractive index of the inner cladding layers 12 and 13 are higher than the refractive index of the material forming the outer cladding layers 14 and 15, where either or both of the outer cladding layers 14 and 15 may comprise air. The thickness of the waveguide core 11 is a function of the wavelength of the photons in the incident photon beam 21 and the size of the concentrated photon beam 23 at the GWPV device 10.

The y-dimension of the waveguide core 11 may be specified to support either or both: (i) a single spatial mode of beam photons traveling along the preferred photon propagating direction, and (ii) multiple spatial modes within the inner cladding layers 12 and 13. By supporting both spatial modes, the GWPV device 10 confines the concentrated photon beam 23 to travel along the waveguide core 11 by establishing total internal refraction conditions at core-to-cladding interfaces 24 and 25. Alternatively, the y-dimension of the waveguide core 11 dimension may be specified larger to support multimode operation. The z-dimension of the waveguide core 11 may on the order of the y-dimension, such that the waveguide core 11 comprises an essentially one-dimensional configuration, that is, a channel-type of waveguide. Alternatively, the z-dimension of the waveguide core 11 may be many times the size of the y-dimension, such that the waveguide core 11 comprises a n essentially two-dimensional configuration suitable for a thin film fabrication process. Or, in yet another exemplary embodiment, the waveguide core 11 may be a combination of both a one-dimensional configuration and a two-dimensional configuration.

It can be appreciated by one skilled in the art that the refractive index difference described above for the waveguide core 11 and the inner cladding layers 12 and 13 produce a cavity that can be tuned to suppress spontaneous emission near the energy band-edge of the photovoltaic material in the waveguide core 11. This suppression feature functions to increase energy conversion in the GWPV device 10. Alternatively, a Bragg type of reflector may be included in the GWPV device 10 to enhance the spontaneous emission suppression feature. For example, one or both inner cladding layers 12 and 13 may comprise metallic material having a higher refraction index and a much shorter absorption depth than that of the photosensitive material in the waveguide core 11.

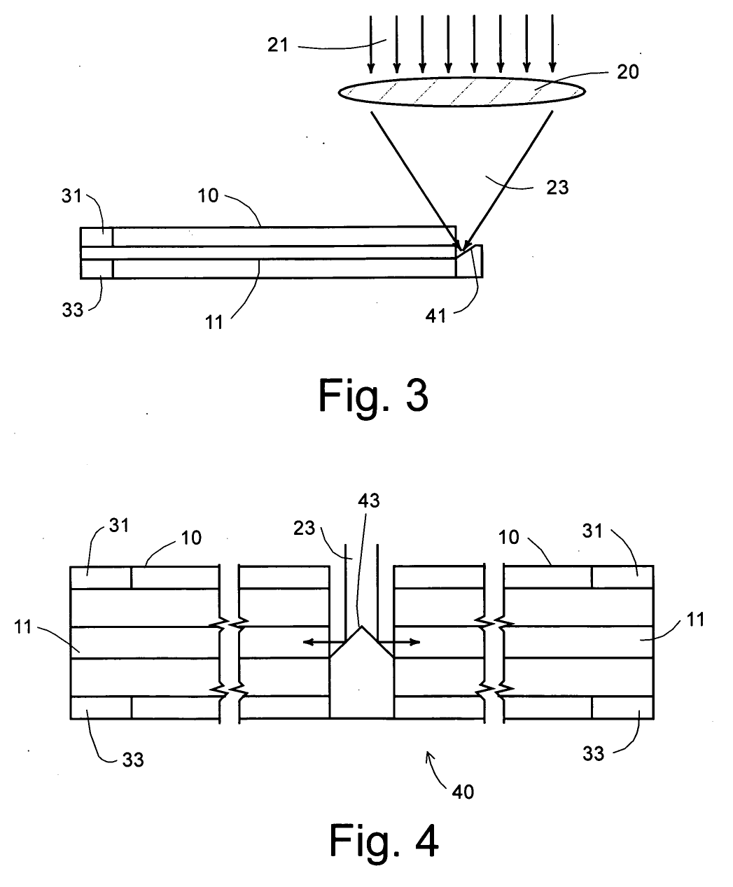

An intermediate optical component or mechanism may be used to direct the concentrated photon beam 23 into the preferred photon propagating direction. As shown in FIG. 3, the intermediate optical component comprises a surface reflector 41 oriented so as to direct the concentrated photon beam 23 into the waveguide core 11 by means of total internal reflection. Alternatively, the intermediate optical component or mechanism may comprise a reflective interface, such as metal coating on an edge surface of a waveguide (not shown), where the coated edge surface could be either a refractive (i.e., non-imaging) type or a reflective type integrated with or within the intermediate optical component or the waveguide core 11. Moreover, the intermediate optical component may comprise part of the waveguide core 11 and may further comprise photosensitive materials. In another exemplary embodiment, shown in FIG. 4, the intermediate optical component or mechanism may comprise a reflective optical component, such as an angled surface reflector pair 43, disposed to produce optical paths between the optical concentrator 20 and two waveguide cores 11. The combination of two GWPV devices 10 and the angled surface reflector pair 43 forms a dual GWPV device 40.

The photon-generated carriers may be extracted from the photosensitive material in the waveguide core 11 via the electrodes 31, 33, and 35, as shown in FIGS. 1, 3, and 4. As can be appreciated by one skilled in the art, since photons enter the photon beam end of the waveguide core 11 in a typical configuration for the GWPV device 10, the size and the positions of the electrodes 31, 33, and 35 on the surface of the waveguide core 11 can be freely defined and optimized depending on the applications. In the configuration shown in FIG. 1, for example, the electrodes 31 and 33 are attached at the end or periphery of the GWPV device 10 so as to avoid potential metal absorption loss if the inner cladding layers 12 and/or 13 used are relatively thin.

Also, the surface area not blocked by the electrodes 31 and 33 may be useful for collecting ambient diffused optical radiation in some device applications. Alternatively, the electrodes 31 and 33 can cover all or part of the lateral surfaces of the GWPV device 10, for transparent or metallic electrodes. This arrangement shortens the electron and hole traveling distance, that is, the distance from electron-hole generation to the electrodes 31 and 33, generally in the y-direction. The electrode 35 may be placed along the waveguide core 11, as shown in FIG. 1, such that photo-generated charge carrier could be extracted by following photon intensity and distribution. Higher carrier density corresponds to higher photo-voltage output as in a concentrated photovoltaic cell.

A minimum length for maximum photon absorption of the waveguide core 11 may be determined by the absorption coefficient of the photosensitive material for the concentrated photon beam 23. The absorption coefficient near the lowest energy bandgap of silicon is about 100 cm⁻¹. A 300 micron traveling distance along the waveguide core 11 corresponds to about 95% absorption of collected photons with energy above the bandgap level of silicon. Accordingly, the GWPV device 10 can be designed to obtain total absorption of essentially all (i.e., >99%) collected photons. This design configuration is particularly useful for photovoltaic cells with indirect bandgap materials such as silicon, and for devices having very thin photo-absorptive regions, such as may be found in organic/Gratzel cells. In certain photovoltaic device applications, a reflective surface 27, shown in FIG. 1, can be provided at a periphery of the waveguide core 11, near the electrodes 31 and 33, so that the minimum waveguide length required for maximum absorption can be reduced by about half.

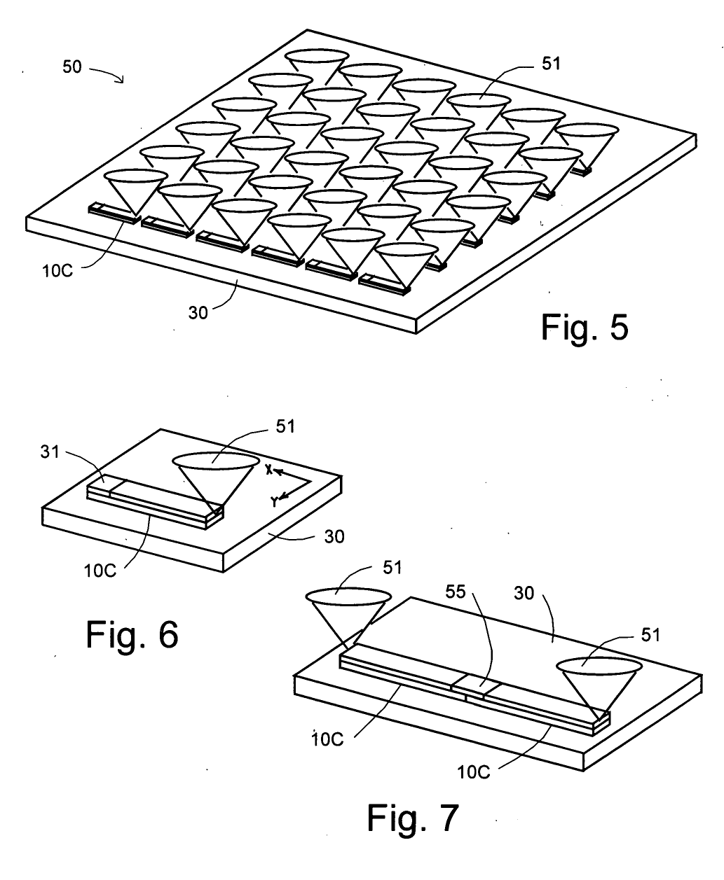

FIG. 5 schematically illustrates an exemplary embodiment of a GWPV array 50 in accordance with the present invention. The GWPV array 50 comprises a plurality of channel-type GWPV devices 10C on a substrate 30. Although a rectangular array of channel-type GWPV devices 10C is shown in the schematic illustration, it should be understood that another geometric configuration, such as a hexagonal array for example, can be used. As best seen in FIG. 6, a GWPV device 10 may be configured as a channel-type GWPV device 10C by having a y-dimension on the order of the z-dimension. Accordingly, the channel-type GWPV device unit 10 may receive the concentrated photon beam 23 via a spherical concentrator 51 disposed at a periphery of the waveguide core 11, as shown.

In the configuration comprising the spherical concentrator 51 and the channel-type GWPV device 10C, there is provided an advantageously large concentration ratio, i.e. the corresponding ratio of concentrator diameter to waveguide length. Depending on application, material growth, and processing, two spherical concentrators 51 may be coupled to a pair of channel-type dual GWPV devices 10C that share a common electrode 55, shown in FIG. 7. Since the length of the channel-type GWPV device 10C is primarily determined by the absorption length of photosensitive material in the waveguide core 11, the diameter of the concentrator 51 can be as small as about twice the length of the corresponding waveguide core 11 in the GWPV array 50 configuration shown in FIG. 5.

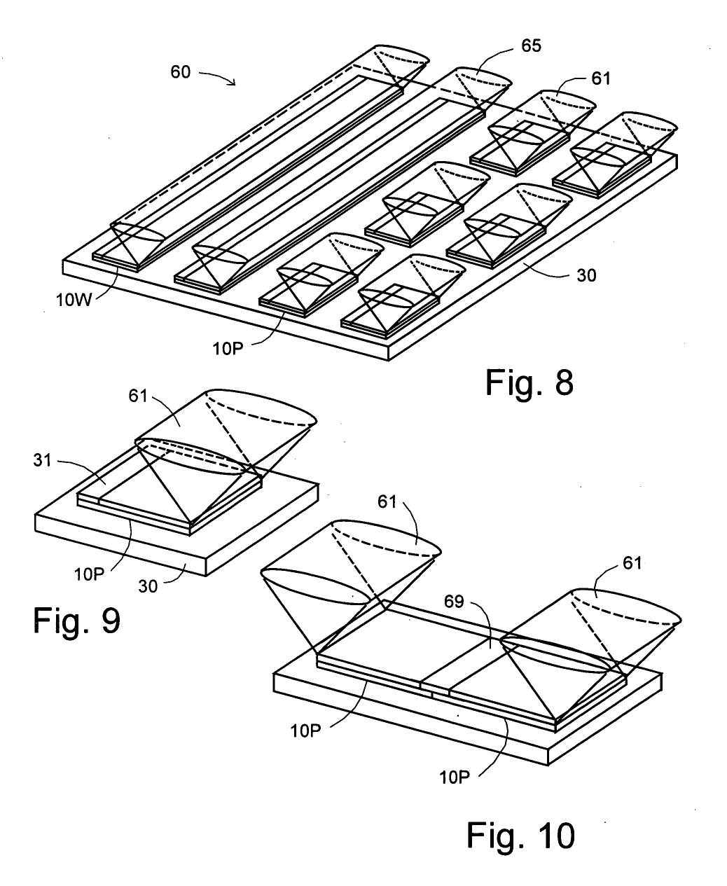

In a silicon-based GWPV device, the diameter of each photon beam concentrator may typically be on the order of millimeters. However, this will not be a limitation since any extra length of the corresponding waveguide will not add significantly to material cost in the GWPV type of devices. Having an extendable length of the waveguide provides for an advantage in configuration flexibility of GWPV devices when potentially different techniques are applied during fabrication of the photovoltaic devices. This advantage may also apply to an exemplary embodiment of a GWPV array 60, in accordance with the present invention, shown in FIG. 8.

The GWPV array 60 comprises a plurality of cylindrical concentrators, such as cylindrical lenses 61 and 65 for example, and a plurality of planar-type waveguide GWPV devices 10P and/or wide planar-type waveguide GWPV devices 10W. The lateral y-dimension of the planar-type waveguide GWPV device 10P, shown in FIG. 9, is greater than the lateral y-dimension of the channel-type waveguide GWPV device 10C shown in FIG. 6. The lateral y-dimension of the wide planar-type waveguide GWPV device 10W, shown in FIG. 8, is significantly greater than the lateral y-dimension of the planar-type waveguide GWPV device 10P. Accordingly, the cylindrical concentrator 61 may be used to illuminate an edge or periphery of the planar-type waveguide GWPV device 10P, and the cylindrical concentrator 65 may be used to illuminate an edge or periphery of the wide planar-type waveguide GWPV device 10W. In an alternative embodiment, shown in FIG. 10, a pair of cylindrical concentrators 61 may be used to irradiate pair of planar-type waveguide GWPV devices 10P that share a common electrode 69.

It should be understood that the GWPV devices 10, 10C, 10P, and 10W, which are shown above as configured in a horizontal geometry, may also be configured in a vertical geometry, depending on application requirements, material growth, processing, and chip/module packaging techniques used. The vertical geometry has the advantage of concentrating light directly into the corresponding GWPV device without a diverting component, such as the spherical lenses 51 and cylindrical lenses 61 and 65. The horizontally configured waveguide arrays, shown in FIGS. 5 and 8, have lower profiles (i.e., are thinner) and have the advantage of incorporating thin-film technology. In both horizontal and vertical waveguide configurations, the individual waveguides can be fabricated in place by many available techniques such as: direct layer deposition, thin wafer transferring, wafer cutting, ribbon cutting, and many more well known to those skilled in the relevant art. Moreover, although the particular configurations shown in FIGS. 5 and 8 comprise different types of photon concentrators and corresponding waveguides as examples of a module design, a GWPV device in accordance with the present invention may comprise other combinations of concentrator type and waveguide type.

It can be appreciated by one skilled in the art that the GWPV devices disclosed herein have an advantage as regards photovoltaic material cost and improved conversion efficiency. However, further improvements can be made to address operating issues including: light tracking, tracking system complications, device heating at high photon concentration, and collection of diffused and ambient sunlight. The GWPV device configurations described herein, however, maintain advantages of concentration to efficiency, while avoiding the drawbacks of concentrating systems taught in the present state of the art. Moreover, the GWPV devices can be designed to be as compact as state-of-the-art flat panel solar cells, as explained below.

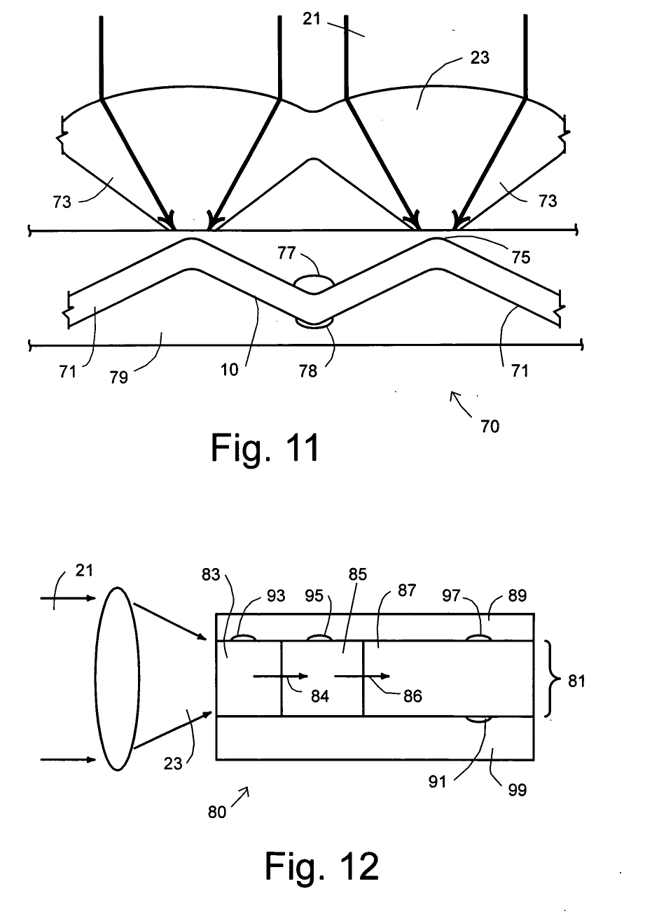

A silicon-based GWPV device can be fabricated using film deposition techniques known in the present state of the art. FIG. 11 is a schematic side view of a thin-film GWPV device 70 comprising a plurality of lambda-shaped (Λ-shaped) waveguides 71 and a plurality of optical concentrators 73 formed adjacent the lambda-shaped waveguides 71. Although only two optical concentrators 73 and two lambda-shaped waveguides 71 are shown, it should be understood that the silicon-based GWPV device is not restricted to this number, and that any number can be specified in accordance with the fabrication methods used. Depending on application, each Λ-shaped waveguide 71 may comprise a pair of channel-type GWPV devices 10C, a pair of planar-type GWPV devices 10P, or a pair of planar-type GWPV devices 10W, configured as shown and deposited on a substrate film 79. In an exemplary embodiment, adjacent waveguides 71 form an obtuse angle, that is, an angle greater than 90 degrees.

The shape of the optical concentrator 73 is preferably specified to conform to the geometry of the corresponding Λ-shaped waveguide 71. The incident photon beam 21 passes through the optical concentrator 73 to form the concentrated photon beam 23 on an outer surface 75 of the Λ-shaped waveguide 71. The outer surface 75 of the Λ-shaped waveguide 71 functions to divert the concentrated photon beam 23 into either or both of the GWPV devices 10 (or 10C or 10P or 10W) of the Λ-shaped waveguide 71. The Λ-shaped configuration provides an advantage to increase light coupling efficiency into waveguide while maintaining growth and processing technology advantages such as large area film deposition and layer coating.

The refraction index for silicon is about 3.5 for photons with energy near the silicon bandgap. The total reflection angle inside a waveguide may be about 20 degrees for a glass interface, and about 15 degrees for an air interface. This relatively large difference in indices of refraction can provide adequate space for a waveguide design such as wedging and bending. The size and shape of the Λ-shaped feature can be engineered to efficiently capture most of or all of the incident photon beam 21 into the waveguide core and cladding of the GWPV devices 10, 10C, 10P, and 10W, and may be configured to provide a relatively wide acceptance angle. Among the characteristics desirable in a photovoltaic module are: a relatively thin configuration, a relatively small mass, and a relatively wider accepting angle. The angle for the lambda feature could be specified over a broad range, depending on applications and material processing techniques.

In an alternative exemplary embodiment, the total internal reflection configuration comprising the surface reflector 41, shown in FIG. 3, can be used for a half “side wing” of the Λ-shaped waveguide 71 having a lambda angle of about 90 degrees. Furthermore, a half side wing of the Λ-shaped waveguide 71 can also be curved instead of planar, depending on the processing techniques. By combining imaging and non-imaging optical techniques, many other types of concentrators or collectors, in addition to those disclosed in the figures of this invention, could also be used in the thin-film GWPV device 70.

Regarding thermal issues in conventional concentrating photovoltaic cells, the thin-film GWPV device 70 configuration also provides an advantage in heat transfer and dissipation. In an application without the need for a transparent electrode, highly thermal conductive substrates can be used to further enhance the heat dissipating ability in the GWPV devices with favorable concentrating ratios.

Regarding the issue of collecting diffused solar light in conventional concentrating photovoltaic cells, the waveguide film cell configuration, as exemplified by the thin-film GWPV device 70, can collect diffused light via the substrate film 79. Source and drain electrodes 77 and 78 may be connected at an end of the Λ-shaped waveguide 71 for extraction of the photon-generated carriers. The open area of the outer surface 75 on the Λ-shaped waveguide 71 provides means by which diffused light is absorbed and, further, maintains the advantages of a conventional thin film cell. An improvement can be made when both source and drain electrodes 77 and 78 are placed on back or bottom side of the substrate film 79.

As can be appreciated by one skilled in the relevant art, the silicon material used in the photovoltaic devices disclosed herein can be replaced by amorphous silicon (a-Si) to provide for a thinner layer thickness. Although a-Si has a higher optical absorption coefficient than does crystalline silicon, the thinner layer thickness feature has preferred stability in “light soaking.”

Beside silicon, many other thin film materials, such as those based on groups III-V semiconductors (e.g., GaAs, CdTe, and CIGS) have been developed for solar energy conversion processes. These solar cells may have higher conversion efficiency than a silicon thin film cell, but have the disadvantage of incurring higher material and processing costs. Such expensive material is subject to ever-increasing price adjustments due to their scarcity, which is detrimental to large-scale production in the solar cell industry. Accordingly, silicon has achieved prominence from a material availability perspective.

Although silicon is one of the most available materials found on the earth, increasingly large amounts are required to meet the demands of solar energy needs, in addition to its heavy usage in the silicon-based electronic industry. With recent initiatives of clean energy goals and the accelerations of world wide investment in solar cell technologies, the process of obtaining purified silicon raw material may eventually become a bottleneck for not only the solar industry, but also the silicon-based large scale electronic industrial sector. To meet all the challenges, more efficient silicon photovoltaic cells with less material consumption are required, and may eventually hit the target of low cost per watt of energy.

A solar photovoltaic cell with a single component of semiconductor material may typically have limited efficiency. For example, in a silicon cell, about 25% of solar light (i.e., optical radiation) lies below the energy gap of silicon and cannot be absorbed to generate photovoltaic charges. On the other hand, absorbed photons with higher energy than the silicon bandgap may generate high-energy electrons and holes, which lose their excess energy above the bandgap to lattice phonons when they relax down to the band edge before reaching an electrode. This extra energy makes no contribution to the photon-induced current but rather is eventually wasted as heat.

In a multi-junction tandem cell, however, several material components, each having a different absorption bandgap, cover the broader range of the solar spectrum. The higher energy photons are absorbed by a wider bandgap material component corresponding to higher voltage output. The thermal energy loss to the material lattice is thus mitigated. As can be appreciated by one skilled in the art, a solar or photovoltaic cell having different material components may provide for greater photon-to-electrical energy conversion than a comparable device having a single material component. In the present state of the art, commercially-available multi-junction tandem cells on germanium substrates may achieve an over 30% conversion efficiency. Nevertheless, this configuration has limited applications because of expensive material components and associated high production costs. A relatively high-efficiency cell based on silicon material is preferable.

Amorphous silicon has a higher energy gap than crystalline silicon, which may make amorphous silicon a preferred candidate as a higher energy component. Thin film a-Si cells have been developed with efficiency comparable to thin film crystalline silicon cells, although operating stability may remain a major concern. Another silicon-based candidate may be nano-sized crystalline silicon (nc-Si). The energy gap of nc-Si depends strongly on the size of the nano-crystal. With the fast developments of nano-technology, the size and informality control are becoming more feasible towards to the practical device applications. It is anticipated that the silicon based material family may be capable of covering about 75% of the solar source at AM 1.5, and a higher percentage at terrestrial AM 1.0.

High efficiency multi-junction tandem cells tend to be relatively expensive because of costly material sources and high production costs due to very restricted material and growth conditions. Each material component must have a proper energy bandgap, and the lattice constant of each component material component must be closely matched to have smooth interface during the growth process. Overall performance depends also on the each layer's current contribution. Often, these layers are designed to match current generated, as electrons and holes must traverse through all layers before reaching the electrodes.

FIG. 12 schematically depicts a multiple core material GWPV device 80 having a waveguide core 81 comprising core component cells of different photosensitive materials. In the example provided, individual core component cells 83, 85, and 87 comprise materials having different energy bandgaps. Preferably, the core component cells 83, 85, and 87 are laterally aligned along the preferred photon propagating direction, and bounded by a first inner cladding 89 and a second inner cladding 99 to define the waveguide core 81. Each core component cell 83, 85, and 87 has a corresponding electrode 93, 95, and 97, and shares a common electrode 91. The concentrated photon beam 23 is transmitted to the core component cell 83, where charge carriers are generated and are removed via the electrode 93. A remaining portion 84 of the concentrated photon beam 23 is transmitted to the core component cell 85 where other charge carriers are generated and are removed via the electrode 95. A smaller portion 86 of the concentrated photon beam 23 is transmitted to the core component cell 87 where still other charge carriers are generated and are removed via the electrode 97.

A conventional multi-junction tandem photovoltaic cell may have a “layer stacked” configuration in which photon-generated carriers typically undergo large losses when drifting across the multiple junctions before reaching the electrodes. Furthermore, as incident photons travel through the stacked, highly-doped component layers, the photons may incur strong absorption losses due to the impurities in the doped regions. However, in the disclosed multiple core material configuration, as exemplified by the GWPV device 80, photon-generated carriers can be extracted in a direction generally orthogonal to the preferred photon propagating direction, that is in the y-direction. Each core component cell 83, 85, and 87 can extract electrons and holes independently at a relatively short distance (i.e., on the order of film thickness). In addition, the disclosed multiple core material configuration provides for more flexibility in design as current matching is not generally required.

The interfaces between the different material component cells in the GWPV device 80 generally require optical quality only, which is at sub-wavelength scale. The sub-wavelength requirement allows for less precision in the fabrication of photovoltaic devices compared to lattice matching requirements in conventional multi-junction tandem photovoltaic cells. This allows for greater latitude in material processing, and even relaxes material candidacy requirements since no lattice-matching growth may be necessary. The loss in the doped regions is expected to be much smaller when guided waves travel parallel to the layers, in accordance with the present invention, especially when the waveguide core is intrinsic, as described above. Therefore, conversion efficiency of the multiple core material GWPV cell configuration can approximate the theoretical conversion limit. By adding one more component with lower bandgap, such as germanium or potential polymers, to cover the photons with energy below the silicon bandgap energy, ultra high conversion efficiency can be achieved in silicon-based multiple core material GWPV cells.

The concept and mechanism of orthogonal electron-photon transport in a multiple core material GWPV device can be extended to other material systems, such as CdTe and CdS, for example. Many thin-film processing techniques, such as wafer bonding, transferring, and wafer cutting, for example, can be used to make the multi-material components waveguide. The geometry of the waveguide, such as the lambda shape described above, can also be used depending on applications. Moreover, the concentrators and diverting components or mechanisms disclosed above can also be used with the multiple core material GWPV device 80.

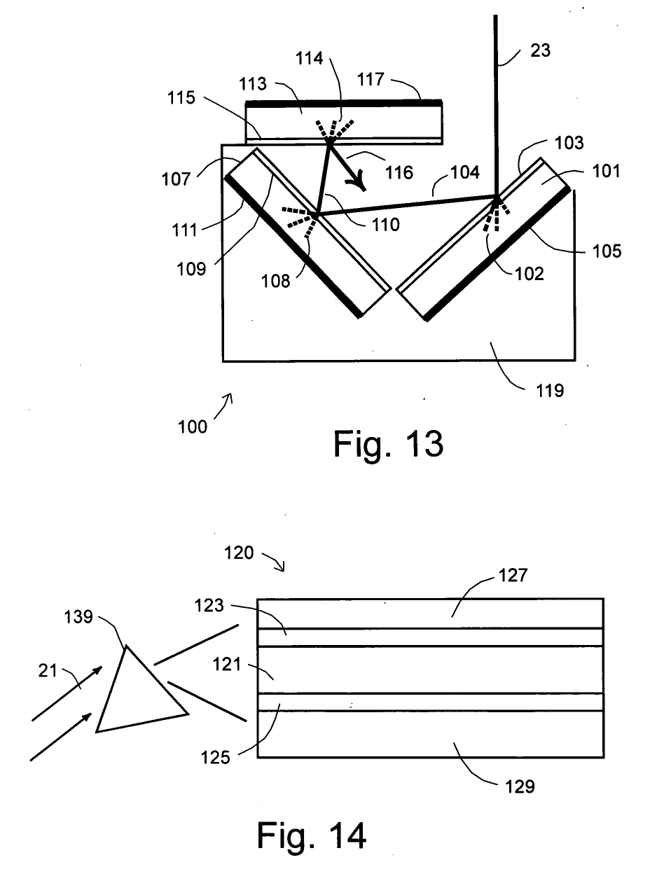

In an alternative exemplary multiple core material configuration embodiment, the core component cells may form a non-planar configuration for confining and guiding the concentrated photon beam 23 to multiple photosensitive materials. There is shown in FIG. 13 a photon confining photovoltaic device 100 comprising a first photovoltaic cell 101 formed from a photosensitive material having a relatively wide bandgap. The first photovoltaic cell 101 comprises a wavelength selective coating 103 and a metallic electrode 105. The wavelength selective coating 103 may be specified to substantially match transmitted input photon beam energy bandwidth with the bandgap absorption for the photosensitive material in the first photovoltaic cell 101. A portion 102 of the input photon beam energy, corresponding to a range of bandgaps matching the first photovoltaic cell 101 material, is substantially transmitted through the wavelength selective coating 103 into the first photovoltaic cell 101. A portion 104 of the input photon beam energy, corresponding to a range of bandgaps smaller than the first photovoltaic cell 101 material, is substantially reflected from the wavelength selective coating 103 and from the metallic electrode 105. The second photovoltaic cell 107 is disposed as shown to receive the reflected portion 104 of photon beam energy from the first photovoltaic cell 101.

The second photovoltaic cell 107 comprises a wavelength selective coating 109 and a metallic electrode 111. The wavelength selective coating 109 is specified to substantially match transmitted input photon beam energy bandwidth with the bandgap absorption for the photosensitive material in the second photovoltaic cell 107. The photosensitive material in the second photovoltaic cell 107 has a bandgap smaller than the bandgap of the photosensitive material in the first photovoltaic cell 101. A portion 108 of the input photon beam energy, corresponding to a range of bandgaps matching the second photovoltaic cell 107 material range, is substantially transmitted through the wavelength selective coating 109 into the second photovoltaic cell 107. Accordingly, a portion 110 of the input photon beam energy, corresponding to a range of bandgaps smaller than the second photovoltaic cell 107 material range, is substantially reflected from the wavelength selective coating 109 to a third photovoltaic cell 113.

The photosensitive material in the third photovoltaic cell 113 has a bandgap smaller than the bandgap of the photosensitive material in the second photovoltaic cell 107. The third photovoltaic cell 113 comprises a wavelength selective coating 115 substantially transparent to input photon beam energy bandwidth with the bandgap absorption for the photosensitive material in the third photovoltaic cell 113. A portion 114 of the input photon beam energy, corresponding to a range of bandgaps matching the third photovoltaic cell 113 material range, is substantially transmitted through the wavelength selective coating 115 into the third photovoltaic cell 113. The wavelength selective coating 115 and a metallic electrode 117 function to reflect a portion 116 of the concentrated photon beam 23 to the first photovoltaic cell 101, where subsequent absorption and reflection are repeated as described above.

The photon confining photovoltaic device 100 may comprise additional photovoltaic cells (not shown) for even higher conversion efficiencies. The placement of the component photovoltaic cells are specified such that the photon beam remains substantially confined inside the cavity-like photon confining photovoltaic device 100 for maximum photon capturing. The cavity-like configuration has advantage of capturing most of the photons in the concentrated photon beam, and especially for capturing spontaneous emission which limits conversion efficiency. The size of each individual photovoltaic cell is a function of the light concentration mechanism, concentration ratio and optics setup, and the numbers of cells. Each individual photovoltaic cell can be a single junction or a multi-junction cell. Non-absorptive media could be air, or transparent polymers and glass or even fluid served as coolant when high concentrating light collector is used. The above discussions related to light concentration and photovoltaic arrays are likewise applicable to the photon confining photovoltaic device 100.

The disclosed GWPV configuration can also be utilized in a device having vertically stacked waveguides. FIG. 14 schematically depicts a stacking waveguide 120, comprising a cladding layer 121 disposed between a first sub-waveguide core 123 and a second sub-waveguide core 125. The sub-waveguide cores 123 and 125 may be disposed between a first substrate layer 127 and a second substrate layer 129, as shown. The sub-waveguide core 123 comprises a material having a wider bandgap than the sub-waveguide core 125 material. The incident photon beam 21 is spectrally dispersed to the sub-waveguide cores 123 and 125 via a dispersive optical component, such as a prism 139 or reflective type of grating. In an exemplary embodiment, the dispersive component can be integrated with the stacking waveguide 120 by using a grating or a photonic structure for photon dispersion. Furthermore, the dispersive component may comprise a photosensitive material integrated with the stacking waveguide 120.

Certain hybrid device configurations may not include the dispersive component. For example, a germanium cell can be stacked onto a silicon cell. The germanium cell can absorb photons having energy lower than the silicon bandgap energy, although higher-energy photon would be absorbed as well. In another exemplary embodiment, each stacked photosensitive material has a narrow-energy bandwidth. In this configuration, each cell layer functions to extract out photo-generated charges corresponding to the narrow-energy bandwidth for that cell layer, where a cell layer may comprise a polymers or a nano-crystalline solid having a narrow absorption band.

In accordance with the present invention, each sub-waveguide core is electrically connected to at least one corresponding contacting electrode. This type of configuration provides an advantage in material growth and production. For example, two or more sub-waveguides can be made separately and then integrated or grown together. As can be appreciated, the sub-waveguide length required for maximum absorption in the material component for higher-energy photons is usually much shorter than that of a material component for low-energy photons. In an alternate exemplary embodiment, the two sub-waveguides 123 and 125 may have different waveguide lengths.

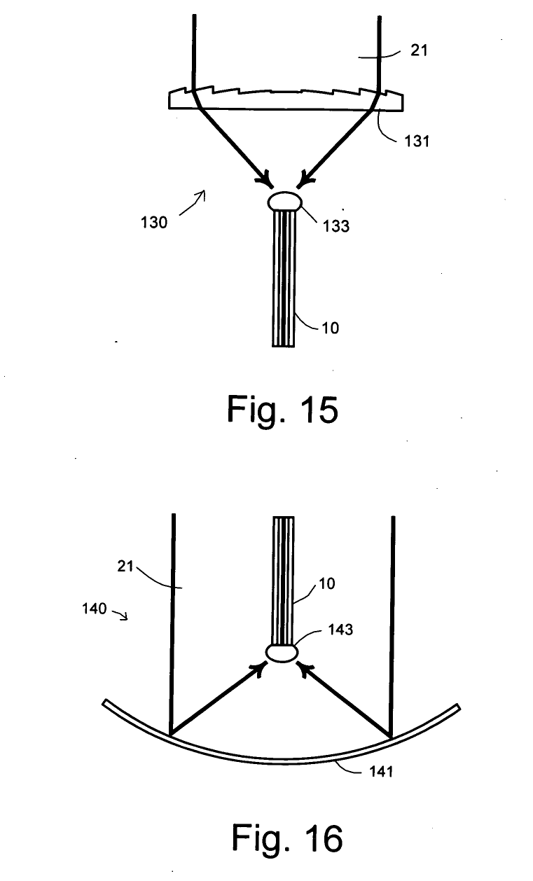

A GWPV device configuration is also suitable for relatively high photon concentration systems. In an exemplary embodiment, a transmission-type high-photon concentration system 130 may comprise a Fresnel lens 131 concentrating the incident photon beam 21 onto a condenser 135 for ultimate transmission to the GWPV device 10, as shown in FIG. 15. In an alternative exemplary embodiment, a reflection-type high-photon concentration system 140 may comprise a surface reflector 141 positioned to converge the incident photon beam 21 onto a condenser 143 for ultimate transmission to the GWPV device 10, as shown in FIG. 16.

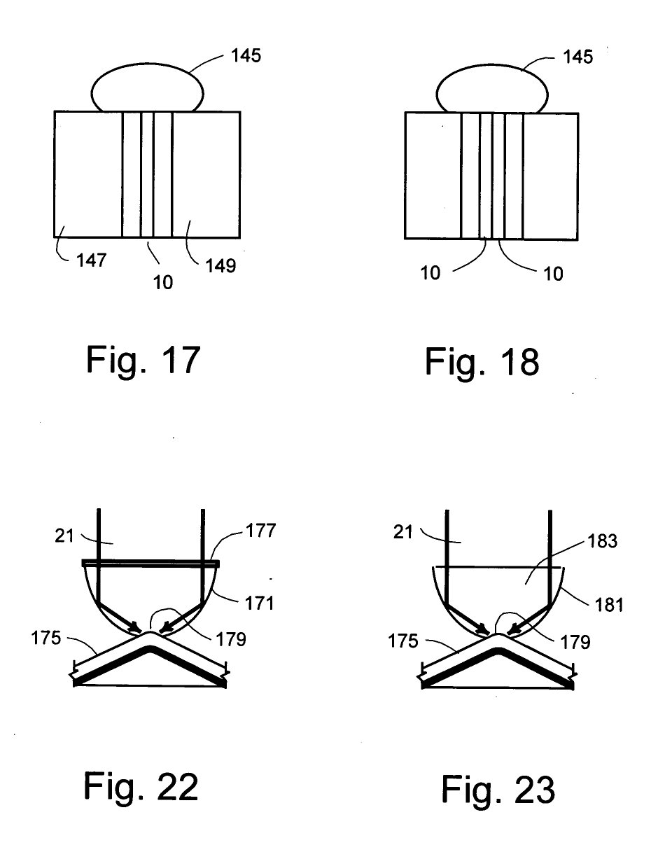

Depending on the concentration ratio achieved by the concentration system, or depending on the size of the respective concentrator, a second photon beam concentrator 145 shown in FIG. 17 can be used. The second concentrator 145 may be disposed at one end or periphery of a GWPV device 10, where the GWPV device 10 is bounded by a pair of electrodes 147 and 149 that also function as heat dissipaters. For a very high concentration system, there may be a modest reduction in required photovoltaic material consumption by using a GWPV device configuration. However, many GWPV device features such as: short carrier path, unlimited absorption length, and flexible configurations, remain advantageous for improving overall system performance. Most importantly, the relatively thin GWPV device has an advantage in heat dissipation, via the electrodes 147 and 149, which advantage is directly related to device performance and cost reduction in the high concentration system.

Because photons are condensed into the GWPV device from the waveguide end, most of the lateral surface of the waveguide can be placed in contact with a highly thermal conductive material layers, such as the electrodes 147 and 149, for advantageous heat spreading or dissipation by conduction. That is to say, a highly thermally conductive substrate may be chosen for thin layer growth. It can be appreciated that, without the limitation of providing a transparent substrate or electrode for the GWPV device 10, for example, the configuration of a GWPV device allows for more available material candidates that may be suitable for waveguide cladding and heat dissipating.

Depending on the concentration ratio, the physical dimension requirements, and the type of concentrators used, two or more GWPV devices 10 can be bonded together as shown in FIG. 18. The second condenser 145 may be integrated with, or even made of, another photovoltaic cell that has the material component for the higher energy photons, such as those in multi-components cells. The concepts of electrode distribution and multi-component materials discussed above also apply to configurations shown in FIGS. 17 and 18. The photons can be collected from either or both ends of the waveguide. It can be appreciated that the GWPV device configuration adds more flexibility to allow for exploring many new device configurations.

Organic solar cells have received great attention because of their light weight, flexibility, and most importantly, their potential low cost production. Although the efficiency and reliability of organic solar cells are not competitive at this stage in comparison with traditional silicon-based solar cells, organic solar cells remain very attractive to many potential applications, such as portable devices, and applications where the lifetime of the device is of less concern. With attractive material synthesis capabilities, organic solar cells have the potential to cover most of the solar spectrum, which is an important property if higher efficiency photovoltaic cells are to be realized.

One critical issue is the need to design a photovoltaic cell having an extremely thin effective photosensitive region. Because of strong exciton bonding energy, photo-generated charges cannot be efficiently extracted from beyond the effective photosensitive region out to electrodes. In a typical application, the thickness of a photosensitive region may be about 50 nm. The coefficient of absorption in energy band averaging would need to be about ten times higher than the coefficient of absorption in a conventional polymer material if a fraction of over 95% of the optical radiation is to be absorbed. Efforts have been made to improve device efficiency by enhancing the exciton dissociation, and by improving the light trapping mechanism via metal reflectors.

In a GWPV device configuration, variable absorption length along the waveguide could benefit the photon absorption in an ultra thin photosensitive layer. If the light guiding or trapping process is relatively efficient, it might even be possible to reduce the thickness of a photo-active layer for more effective electron-hole pair extraction. In addition, a thinner photo-active layer may improve electrical resistance of the associated polymer cell, which is also a very important factor for overall performance and reliability. The required thickness in a conventional organic cell may be determined by the exciton bonding energy and the light absorption length.

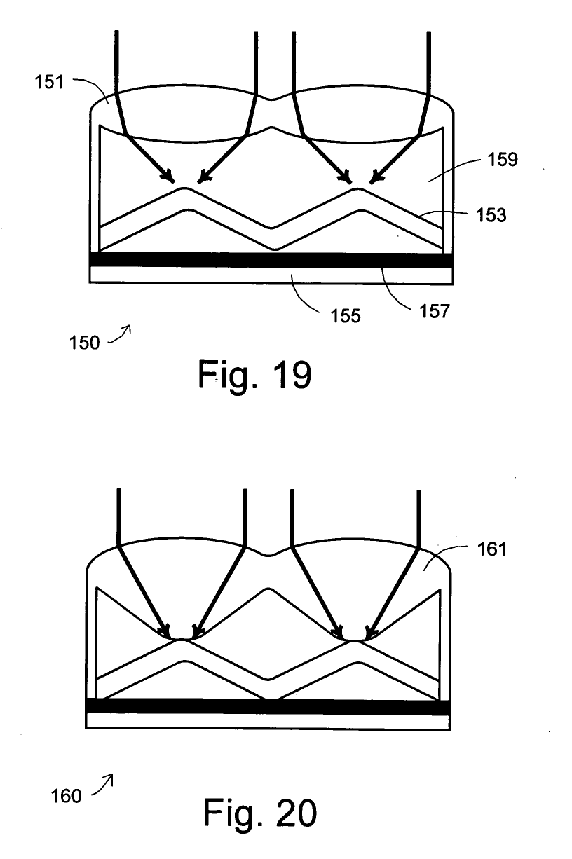

Relaxing the thickness condition for light absorption could potentially help to develop more materials suitable for a higher efficiency cell design. Accordingly, the disclosed GWPV device configuration can be applied to polymer material systems. FIG. 19 shows a GWPV-type polymer device 150 comprising a plurality of focal lenses 151. Each focal lens 151 may comprise a polymer material. The total thickness of the GWPV-type polymer device 150 can be as small as a few millimeters, as described above. Photosensitive layers for a Λ-shaped waveguide 153 may be coated on a thin substrate 155 comprising plastic and may include a metal reflection layer 157.

An air layer 159 may be used as a cladding layer with the waveguide 153. Photosensitive polymer layers can also be disposed as cladding layers on the core of the waveguide 153, where the core comprises non-absorptive or low absorptive material, and may comprise a metal, for example. The waveguide core preferably comprises a material with a higher refraction index than the photosensitive polymer layer to form the waveguide 153, when the photosensitive layer and the substrate are embedded in the media with similar refraction index. Collection of diffused or ambient light is typically improved if the metal reflection layer 157 has been provided. It can be appreciated that the Λ-shaped waveguide 153 serves to increase the light acceptance angle, as discussed above. In an alternative exemplary embodiment of a GWPV-type polymer device, FIG. 20 shows a combination imaging and non-imaging GWPV-type polymer device 160 comprising a plurality of condensers 161.

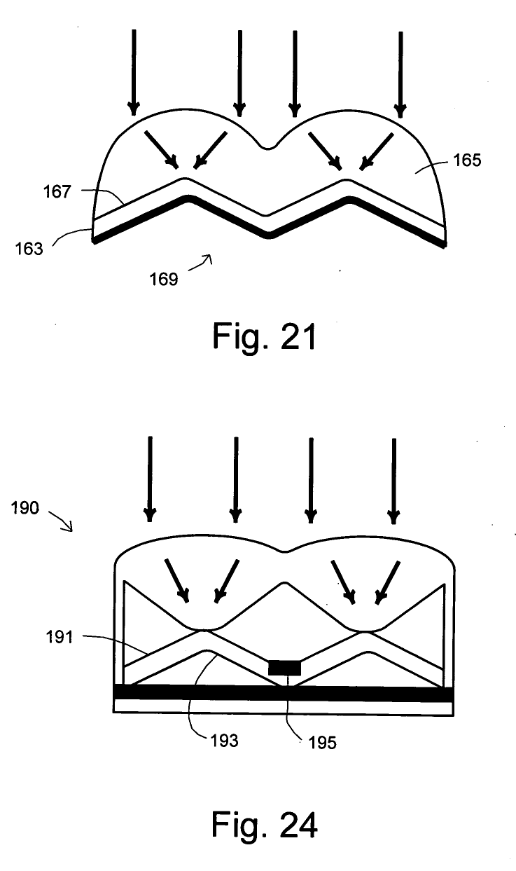

In another advantage offered by a polymer waveguide cell, the corresponding refraction index may be almost matched to the index of refraction for the concentrator, assuring minimum reflection loss. Reflection loss may be mitigated by applying anti-reflection coating between the interfaces of two materials with large index differences. As polymer is easier to process, a photosensitive layer 163 can be directly coated onto a pre-shaped glass or polymer condenser 165, as shown in FIG. 21. In this type of waveguide cell, a thin anti-reflection coating 167 with high optical index may be applied onto the photosensitive layer 163 to form a waveguide core 169 for confining a traveling photon beam.

It can be appreciated that metal layers 139 and 147 in FIGS. 18-20 may be used as electrodes and heat dissipaters, and provide for diffused light collecting. In particular, the metal layer 147 can also be used as a part of a waveguide 149 comprising the photosensitive layer 143. As can be seen in FIGS. 18-20, GWPV-type polymer devices can provide the advantages of the light weight and plastic flexibility of a conventional polymer thin film cell.

The above discussion can also be applied to dye-sensitized photoelectron-chemical cells, or Gratzel cells. The photon capture ability in a Graztel cell or dye-sensitized cell can be improved by increasing the number or the volume of dye molecules attached to large porous surfaces of a host TiO₂. However, the increased porosity of TiO₂ could hinder charge carrier transport—hence the overall cell performance. Applying a GWPV device configuration to a Graztel cell or a dye-sensitized cell could potentially help improve cell performance by using thinner cells, and leading to a higher efficiency cell.

It is known in the relevant art that a Winston type of light collector typically has a wide acceptance angle. The collector can be configured with a metal reflecting type Winston collector 171 comprising an optical concentrator 177, as shown in FIG. 22. The shape of the top 179 of a Λ-shaped waveguide 175 can be finely tuned for maximum collection from the opening of the Winston collector 171. The optical concentrator 177 may comprise either a spherical type or a cylindrical type, as described above, and may be used with either a channel-type or a planar-type GWPV device. Alternatively, a refractive type Winston collector 181 comprising a refractive transparent medium 183, shown in FIG. 22, provides total internal refraction at the interface between the transparent medium 183 and ambient air. Alternatively, a combination of both Winston collectors 171 and 181 may be used. Each type of Winston collector has unique advantages and disadvantages in collecting angles, optical loss, and device making.

The GWPV polymer cell configuration, in accordance with the present invention, can be further extended to a hybrid structure with an inorganic photovoltaic structure, such as a silicon photovoltaic cell. The combination of both types of cells may serve to noticeably improve conversion efficiency compared to a conventional polymer cell, which may have a conversion efficiency of approximately a few percent. A hybrid GWPV device 190, shown in FIG. 24, comprises a GWPV waveguide 191 having a waveguide-type inorganic cell 195 disposed at a vertex of one of the obtuse angles formed by the waveguide 191, as shown. The GWPV hybrid cell 190 provides similar advantages to multi-junction cells. For example, the visible band of solar spectrum is covered by polymer absorption, and near IR radiation is absorbed by silicon. This type of hybrid GWPV devices may provide for a higher conversion efficiency while maintaining advantages of polymer thin film devices.

It is to be understood that the description herein is exemplary of the invention only and is intended to provide an overview for the understanding of the nature and character of the invention as it is defined by the claims. The accompanying drawings are included to provide a further understanding of various features and embodiments of the method and apparatus of the invention which, together with their description serve to explain the principles and operation of the invention. Thus, while the invention has been described with reference to particular embodiments, it will be understood that the present invention is by no means limited to the particular constructions and methods herein disclosed and/or shown in the drawings, but also comprises any modifications or equivalents within the scope of the claims.

What is claimed is:

1. A photovoltaic device comprising:
a first cladding material;
a photosensitive material having an index of refraction larger than said first cladding material index of refraction, said photosensitive material disposed adjacent said first cladding material; and
a second cladding material having an index of refraction smaller than said photosensitive material index of refraction, said photosensitive material disposed between said first cladding material and said second cladding material so as to form a waveguide for confining propagating photons; and
first and second electrodes in electrical contact with said photosensitive material.

2. The device according to claim 1 wherein said first cladding material forms a reflection interface with said photosensitive material, said reflection interface functioning to reflect photons propagating through said photosensitive material.

3. The device according to claim 1 wherein said photosensitive material, said first cladding material, and said second cladding material comprise respective thin films formed on a substrate.

4. The apparatus according to claim 3 wherein said substrate comprises an optical concentrator configured to concentrate a photon beam into said photosensitive material.

5. The device according to claim 3 wherein said waveguide forms an obtuse angle with a second waveguide formed on said substrate.

6. The device according to claim 5 further comprising a silicon photovoltaic cell disposed at a vertex of said obtuse angle.

7. The device according to claim 1 further comprising a second photosensitive material having a narrower bandgap than a bandgap of said photosensitive material, said second photosensitive material disposed to receive photons propagating from said photosensitive material.

8. The device according to claim 1 further comprising an optical concentrator disposed at a periphery of said photosensitive material, said optical concentrator for converting an incident photon beam into a concentrated photon beam for transmission into said photosensitive material.

9. The device according to claim 8 wherein said optical concentrator comprises one of a transmissive optical device and a reflective optical device.

10. The device according to claim 8 further comprising a surface reflector for directing said concentrated photon beam into said photosensitive material.

11. The device according to claim 8 further comprising a third electrode in electrical communication with said photosensitive material, said third electrode disposed between said first electrode and said photosensitive material periphery.

12. The apparatus according to claim 1 further comprising a third cladding material disposed on said first cladding material, said third cladding material having an index of refraction smaller than said first cladding material index of refraction.

13. A photovoltaic device comprising:
a first photosensitive material disposed to receive a photon beam;
a second photosensitive material having a bandgap smaller than said first photosensitive material bandgap, said second photosensitive material disposed to receive a first portion of said photon beam from said first photosensitive material; and
a third photosensitive material having a bandgap smaller than said second photosensitive material bandgap, said third photosensitive material disposed to receive a second portion of said photon beam from said second photosensitive material.

14. The device according to claim 13 further comprising a cladding layer disposed on said first photosensitive material, on said second photosensitive material, and on said third photosensitive material.

15. The device according to claim 13 further comprising a wavelength selective coating disposed on said first photosensitive material, said wavelength selective coating substantially transmissive to a part of said photon beam energy bandwidth matching a bandgap absorption in said first photosensitive material.

16. The device according to claim 13 further comprising a metallic electrode disposed on said first photosensitive material.

17. A method for fabricating a photovoltaic device for conversion of a photon beam into electrical energy, said method comprising the steps of:
depositing a layer of a first cladding material onto a substrate;
depositing a layer of photosensitive material onto said first cladding material, said photosensitive material having an index of refraction larger than said first cladding material index of refraction; and
depositing a layer of a second cladding material onto said photosensitive material, said second cladding material having an index of refraction smaller than said photosensitive material index of refraction.

18. The method according to claim 17 further comprising the step of depositing an electrode onto said substrate, said electrode in electrical contact with said photosensitive layer.

19. The method according to claim 17 further comprising the step of forming a surface reflector on said substrate, said surface reflector oriented so as to direct the photon beam into said layer of photosensitive material.

20. The method according to claim 17 wherein said second cladding layer comprises a material substantially transparent to the photon beam.
